(19) United States
(12) Patent Application Publication
(10) Pub. No.: US 2008/0233722 A1
(43) Pub. Date: Sep. 25, 2008

(54) METHOD OF FORMING SELECTIVE AREA COMPOUND SEMICONDUCTOR EPITAXIAL LAYER

(75) Inventors: Chin-I Liao, Tainan City (TW); Chin-Cheng Chien, Tainan County (TW); Hou-Jun Wu, Changhua County (TW); Po-Lun Cheng, Kaohsiung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 11/690,138

(22) Filed: Mar. 23, 2007

(51) Int. Cl. H01L 33/00

(52) U.S. Cl. 438/508

(57) ABSTRACT

A method of forming a selective area semiconductor compound epitaxy layer is provided. The method includes the step of using two silicon-containing precursors as gas source for implementing a process of manufacturing the selective area semiconductor compound epitaxy layer, so as to form a semiconductor compound epitaxy layer on an exposed monocrystalline silicon region of a substrate.

### BACKGROUND OF THE INVENTION

1. Field of the Invention

The present invention relates to a method of manufacturing a semiconductor device, and more particularly to a method of manufacturing a selective area semiconductor compound epitaxy layer.

2. Description of Related Art

With the rapid development of electronic products e.g. telecommunication products, operating speed of transistors is bound to increase. However, due to the restriction on mobility of electrons and holes in silicon, the applications of the transistors are limited.

The prior art has proposed using silicon germanium (SiGe) epitaxy material as a main component of the source/drain region of the transistor In comparison with silicon, germanium has smaller electron effective mass and hole effective mass. Thus, mobility of electrons and holes can be enhanced with the source/drain region formed by SiGe, and the device performance can be improved.

A single-stage growth process of manufacturing a selective area epitaxy is commonly performed to form a SiGe layer, even though several issues do exist in said process.

Please refer to FIG. 1 which is a schematic sectional view of a conventional transistor. A method of forming a transistor with a SiGe source/drain region 108 includes forming a gate conductive layer 104 and a gate dielectric layer 106; forming a concave 120 on the substrate 100; and performing a single-stage growth process of manufacturing the selective area epitaxy to form SiGe in the concave 120 with the use of SiH₄ as a gas source. However, both a cleaning process ensuring the quality of the SiGe layer and an etching process which are performed before the growth of the SiGe layer etches an insulating material on side walls and on a top corner of an isolation structure 102. And the SiGe layer formed through the single-stage growth process of manufacturing the selective area epitaxy cannot fill out the etched region, so that a gap 110 is formed between the source/drain region 108 and the isolation structure 102. The gap 110 leads to a large leakage current and ion gain degradation because of penetration of a silicide material successively formed on the source/drain region 108, hindering the performance of the transistor.

### SUMMARY OF THE INVENTION

Accordingly, the present invention is to provide a method of forming a selective area semiconductor compound epitaxy layer, so as to prevent a gap from being formed between an isolation structure and a semiconductor compound layer on a source/drain region.

The present invention is to provide a semiconductor device in which the isolation structure and the semiconductor compound layer on the source/drain region are completely jointed, forming no gap in between.

The present invention provides a method of forming a selective area semiconductor compound epitaxy layer. The method includes performing a process of manufacturing the selective area semiconductor compound epitaxy to form a semiconductor compound epitaxy layer on a monocrystalline silicon region on a substrate. A gas source used in the selective area epitaxy growth process comprises two different silicon-containing precursors.

According to the method of forming the selective area semiconductor compound epitaxy disclosed in a preferred embodiment of the present invention, the selective area epitaxy growth process is a multi-stage process, and the silicon-containing precursors used in the selective area epitaxy growth process are different between adjacent stages.

According to the method of forming the selective area semiconductor compound epitaxy disclosed in a preferred embodiment of the present invention, the multi-stage process includes a multi-stage selective area SiGe epitaxy growth process or a multi-stage selective area silicon carbide (SiC) epitaxy growth process.

According to the method of forming the selective area semiconductor compound epitaxy layer disclosed in a preferred embodiment of the present invention, the multi-stage process comprises two stages. A first-stage process of manufacturing the selective area SiGe epitaxy is performed with the use of silane (SiH₄) as the silicon-containing precursors, while a second-stage process of manufacturing the selective area SiGe epitaxy is performed with the use of dichlorosilane (SiH₂Cl₂) as the silicon-containing precursors.

According to the method of forming the selective area semiconductor compound epitaxy layer disclosed in a preferred embodiment of the present invention, the first-stage process of manufacturing the selective area SiGe epitaxy is performed before the second-stage process of manufacturing the selective area SiGe epitaxy. Said first-stage process of manufacturing the selective area SiGe epitaxy is, for example, performed on the following conditions: a pressure ranging from 5 torrs to 50 torrs; a temperature ranging from 550° C. to 750° C. e.g. at 660° C.; the gas source comprising SiH₄, GeH₄, and HCl, wherein a flow rate of SiH₄ ranges from 30 sccm to 200 sccm, a flow rate of GeH₄ ranges from 100 sccm to 200 sccm, and a flow rate of HCl ranges from 80 sccm to 200 sccm. On the other hand, said second-stage process of manufacturing the selective area SiGe epitaxy is, for example, performed on the following conditions: a pressure ranging from 10 torrs to 50 torrs; a temperature ranging from 550° C. to 750° C. e.g. at 660° C.; the gas source comprising SiH₂Cl₂, GeH₄, and HCl, wherein a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm. According to the method of forming the selective area semiconductor compound epitaxy disclosed in a preferred embodiment of the present invention, a thickness of the semiconductor compound epitaxy layer deposited through the first-stage process of manufacturing the selective area SiGe epitaxy is ⅓˜⅚ e.g. 500 Å to 1000 Å of the total thickness of the semiconductor compound layer deposited through the multi-stage process of manufacturing the selective area semiconductor compound epitaxy. A thickness of the semiconductor compound epitaxy layer deposited through the second-stage process of manufacturing the selective area SiGe epitaxy ranges from 100 Å to 500 Å.

According to the method of forming the selective area semiconductor compound epitaxy disclosed in a preferred embodiment of the present invention, the multi-stage process of manufacturing the selective area semiconductor compound epitaxy further comprises performing a third-stage process of manufacturing the selective area SiGe epitaxy after the second-stage process is performed. The silicon-containing gas SiH₄ is used as the gas source during the third-stage process. Said first-stage process of manufacturing the selective area SiGe epitaxy is, for example, performed on the following conditions: a pressure ranging from 5 torrs to 50 torrs; a temperature ranging from 550° C. to 750° C. e.g. at 660° C.; the gas source comprising SiH₄, GeH₄, and HCl, wherein a flow rate of SiH₄ ranges from 30 sccm to 200 sccm, a flow rate of GeH₄ ranges from 100 sccm to 200 sccm, and a flow rate of HCl ranges from 80 sccm to 200 sccm. On the other hand, said second-stage process of manufacturing the selective area SiGe epitaxy is, for example, performed on the following conditions: a pressure ranging from 10 torrs to 50 torrs; a temperature ranging from 550° C. to 750° C. e.g. at 660° C.; the gas source comprising SiH₂Cl₂, GeH₄, and HCl, wherein a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm. Said third-stage process of manufacturing the selective area SiGe epitaxy is, for example, performed on the following conditions: a pressure ranging from 5 torrs to 50 torrs; a temperature ranging from 550° C. to 750° C. e.g. at 660° C.; the gas source comprising SiH₄, GeH₄, and HCl, wherein a flow rate of SiH₄ ranges from 30 sccm to 200 sccm, a flow rate of GeH₄ ranges from 100 sccm to 200 sccm, and a flow rate of HCl ranges from 80 sccm to 200 sccm.

According to the method of forming the selective area semiconductor compound epitaxy disclosed in a preferred embodiment of the present invention, a thickness of the SiGe epitaxy layer deposited through the first-stage process of manufacturing the selective area SiGe epitaxy is 1/10˜⅝ e.g. 100 Å to 500 Å of the total thickness of the SiGe epitaxy layer deposited through the multi-stage process of manufacturing the selective area semiconductor compound epitaxy. A thickness of the SiGe epitaxy layer deposited through the second-stage process of manufacturing the selective area SiGe epitaxy is ⅙˜⅝ e.g. 200 Å to 500 Å of the total thickness of the SiGe epitaxy layer deposited through the multi-stage process of manufacturing the selective area semiconductor compound epitaxy. And a thickness of the SiGe epitaxy layer deposited through the third-stage process of manufacturing the selective area SiGe epitaxy is 1/10˜⅝ e.g. 200 Å to 500 Å of the total thickness of the SiGe epitaxy layer deposited through the multi-stage process of manufacturing the selective area semiconductor compound epitaxy.

According to the method of forming the selective area semiconductor compound epitaxy disclosed in a preferred embodiment of the present invention, the first-stage process of manufacturing the selective area SiGe epitaxy is performed after the second-stage process of manufacturing the selective area SiGe epitaxy. Said first-stage process of manufacturing the selective area SiGe epitaxy is, for example, performed on the following conditions: a pressure ranging from 5 torrs to 50 torrs; a temperature ranging from 550° C. to 750° C. e.g. at 660° C.; the gas source comprising SiH₄, GeH₄, and HCl, wherein a flow rate of SiH₄ ranges from 30 sccm to 200 sccm, a flow rate of GeH₄ ranges from 100 sccm to 200 sccm, and a flow rate of HCl ranges from 80 sccm to 200 sccm. On the other hand, said second-stage process of manufacturing the selective area SiGe epitaxy is, for example, performed on the following conditions: a pressure ranging from 10 torrs to 50 torrs; a temperature ranging from 550° C. to 750° C. e.g. at 660° C.; the gas source comprising SiH₂Cl₂, GeH₄, and HCl, wherein a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm.

According to the method of forming the selective area semiconductor compound epitaxy disclosed in a preferred embodiment of the present invention, the thickness of the semiconductor compound epitaxy layer deposited through said first-stage process of manufacturing the selective area SiGe epitaxy ranges from 200 Å to 500 Å, and the thickness of the semiconductor compound epitaxy layer deposited through the second-stage process of manufacturing the selective area SiGe epitaxy is ⅙˜⅚ e.g. 100 Å to 1000 Å of the total thickness of the semiconductor compound epitaxy layer deposited through the multi-stage process of manufacturing the selective area semiconductor compound epitaxy.

According to the method of forming the selective area semiconductor compound epitaxy disclosed in a preferred embodiment of the present invention, the selective area epitaxy growth process uses a combination of the two different silicon-containing precursors as the gas source. The combination comprises SiH₄ and SiH₂Cl₂.

The present invention further provides a semiconductor device including a substrate, an isolation structure, a doped semiconductor compound epitaxy layer, and a gate structure. A trench is formed on the substrate, and the isolation structure is disposed in the trench which defines an active region. The active region comprises a pair of concaves. The doped semiconductor compound epitaxy layer is disposed in the pair of concaves and is extended to cover a top corner of the isolation structure as a source/drain region. The gate structure is disposed on the active region between the pair of concaves and is extended to a portion of the isolation structure.

According to the semiconductor device disclosed in a preferred embodiment of the present invention, the doped semiconductor compound comprises a doped SiGe or a doped SiC.

According to the semiconductor device disclosed in a preferred embodiment of the present invention, the semiconductor device further comprises a source/drain extension region disposed in the substrate between the source/drain region and the gate structure.

In the present invention, the multi-stage process of manufacturing the selective area semiconductor compound epitaxy is performed to form the semiconductor compound epitaxy layer on the source/drain region. No gap exists between the isolation structure and the semiconductor compound epitaxy layer formed in this process, so as to prevent ion gain degradation and the large leakage current induced through the single-stage process of manufacturing the selective area semiconductor compound epitaxy.

In order to the make aforementioned and other objects, features and advantages of the present invention comprehensible, preferred embodiments accompanied with figures are described in detail below.

### BRIEF DESCRIPTION OF THE DRAWINGS

FIG. 1 is a schematic sectional view of a conventional transistor.

FIGS. 2A through 2D are schematic sectional views showing the steps for forming a semiconductor device according to an embodiment of the present invention.

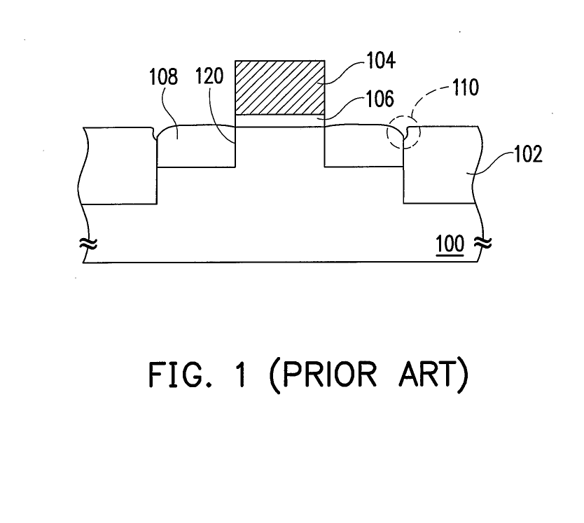

### DESCRIPTION OF EMBODIMENTS

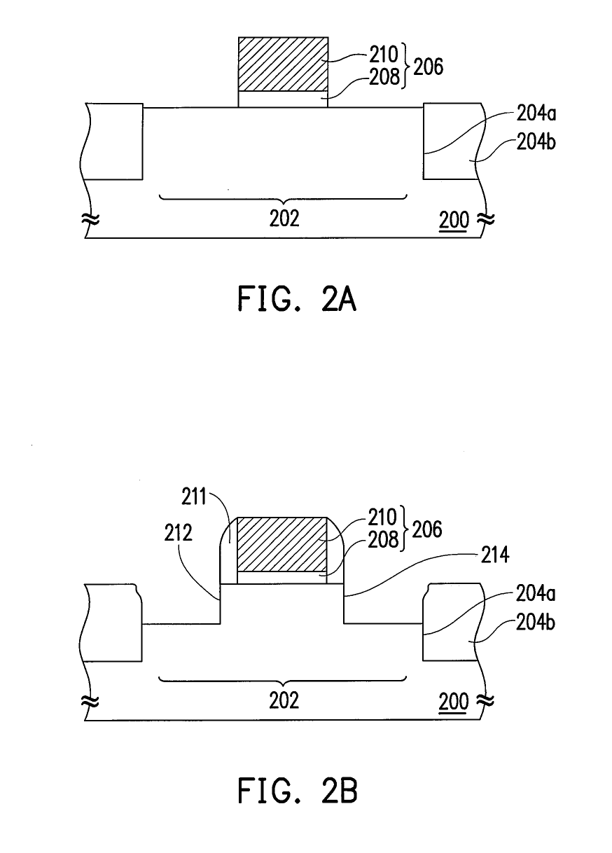

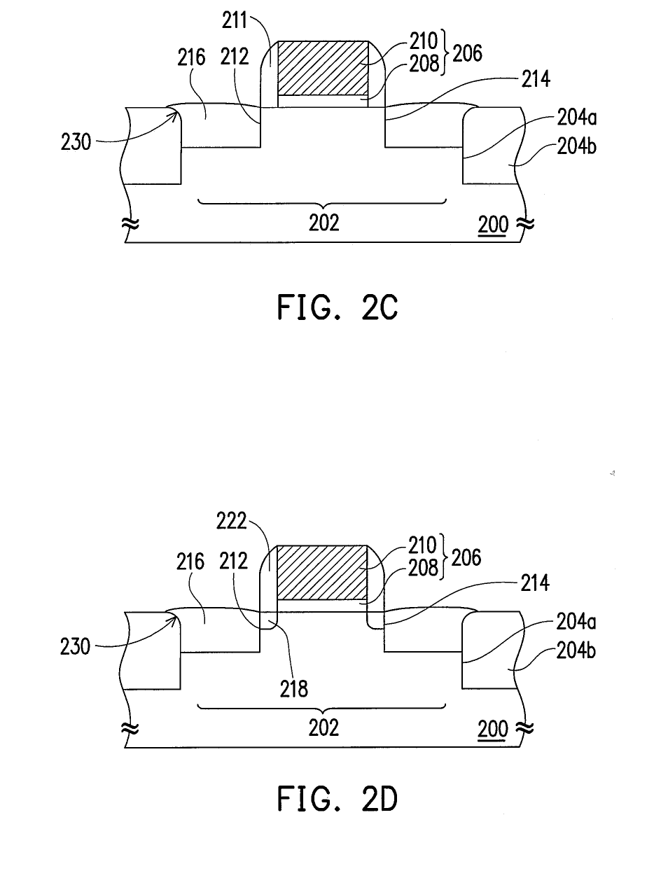

FIGS. 2A through 2D are schematic sectional views showing the steps for forming a semiconductor device according to an embodiment of the present invention.

As shown in FIG. 2A, a substrate 200 e.g. a monocrystalline silicon substrate is provided. A trench 204a is formed in the substrate 200, and an isolation structure 204b is formed in the trench 204a so as to define an active region 202. The isolation structure 204b is made of an insulating material e.g. silicon oxide and is formed by performing a chemical vapor deposition process, for example.

Then, a gate structure 206 is formed on the substrate 200 within the active region 202. The gate structure 206 is composed of a gate dielectric layer 208 and a conductive layer 210. Here, the gate structure 206 is formed by forming a dielectric material layer (not shown) on the substrate 200 within the active region 202. The dielectric material layer is made of silicon oxide, for example. Next, a conductive material layer (not shown) is formed on the dielectric material layer to completely cover the substrate 200. The conductive material layer is made of polysilicon or doped polysilicon, for example. Thereafter, a photolithography process and an etching process are performed to pattern the conductive material layer and the dielectric material layer. The conductive layer 210 and the gate dielectric layer 208 are then formed.

Afterwards, referring to FIG. 2B, a pair of spacers 211 are formed on the sidewall of the gate structure 206, and then a pair of concaves 212 and 214 are formed on the substrate 200 at both sides of the spacers 211. A cleaning process is usually performed before the growth of the SiGe layer so as to ensure the quality thereof. Both the cleaning process and the etching process performed after formations of the concaves 212 and 214 etches side walls and a top corner of the isolation structure 204, deforming the isolation structure 204b as is shown in the figure.

Next, referring to FIG. 2C, after the cleaning process is performed, the selective area epitaxy growth process as is provided in the present invention is performed. With the use of different silicon-containing precursors, the semiconductor compound epitaxy layer e.g. the SiGe layer or the SiC layer is grown in the concaves 212 and 214, and a doped region is formed in the semiconductor compound epitaxy layer as a source/drain region 216. According to the process of manufacturing the selective area semiconductor compound epitaxy provided in the present invention, the semiconductor compound epitaxy layer on the source/drain region 216 extends and covers the top corner 230 of the isolation structure 204b.

Thereafter, referring to FIG. 2D, the spacers 211 are removed and then source/drain extension region 218 is formed in the substrate 200 between the source/drain region 216 and the gate structure 206 by using an ion implantation process. Next, spacers 222 are formed on the sidewall of the gate structure 206.

In one embodiment, the semiconductor compound epitaxy layer is a SiGe layer, and the selective area epitaxy growth process is a multi-stage process of manufacturing the selective area semiconductor compound epitaxy, which comprises two stages in the process of manufacturing the selective area SiGe epitaxy layer. A first-stage process of manufacturing the selective area SiGe epitaxy layer uses SiH₄ as silicon-containing precursors, while a second-stage process uses SiH₂Cl₂ as the silicon-containing precursors.

The first-stage process of manufacturing the selective area SiGe epitaxy is, for example, performed under a pressure ranging from 5 torrs to 50 torrs and a temperature ranging from 550° C. to 750° C. Said first-stage process is, for example, performed at 660° C. in a chemical vapor deposition reaction chamber. The gas source flowed into the reaction chamber includes a combination of SiH₄, GeH₄, and HCl. For example, a flow rate of SiH₄ ranges from 30 sccm to 200 sccm, a flow rate of GeH₄ ranges from 100 sccm to 200 sccm, and a flow rate of HCl ranges from 80 sccm to 200 sccm. A thickness of the SiGe epitaxy layer deposited through said first-stage process of manufacturing the selective area SiGe epitaxy is ⅓˜⅚ e.g. 500 Å to 1000 Å of the total thickness of the SiGe epitaxy layer deposited through the multi-stage process of manufacturing the selective area SiGe epitaxy.

After the first-stage process of manufacturing the selective area SiGe epitaxy is performed, the second-stage process of manufacturing the selective area SiGe epitaxy is carried out. The second-stage process of manufacturing the selective area SiGe epitaxy is, for example, performed under a pressure ranging from 10 torrs to 50 torrs and a temperature ranging from 550° C. to 750° C. Said second-stage process is, for example, performed at 660° C. in the chemical vapor deposition reaction chamber. The gas source flowed into the reaction chamber includes a combination of SiH₂Cl₂, GeH₄, and HCl. For example, a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm. A thickness of the SiGe epitaxy layer deposited through said second-stage process of manufacturing the selective area SiGe epitaxy ranges from 100 Å to 500 Å, for example.

In one embodiment, the semiconductor compound epitaxy layer is a SiGe layer, and the selective area epitaxy growth process is a multi-stage process of manufacturing the selective area semiconductor compound epitaxy layer, which comprises three stages in the process of manufacturing the selective area SiGe epitaxy layer. Both a first-stage process and a third-stage process of manufacturing the selective area SiGe epitaxy use SiH₄ as a silicon-containing precursors, while a second-stage process uses SiH₂Cl₂ as the silicon-containing precursors.

The first-stage process of manufacturing the selective area SiGe epitaxy is, for example, performed under a pressure ranging from 5 torrs to 50 torrs and a temperature ranging from 550° C. to 750° C. Said first-stage process is, for example, performed at 660° C. in a chemical vapor deposition reaction chamber. The gas source flowed into the reaction chamber includes a combination of SiH₄, GeH₄, and HCl. For example, a flow rate of SiH₄ ranges from 30 sccm to 200 sccm, a flow rate of GeH₄ ranges from 100 sccm to 200 sccm, and a flow rate of HCl ranges from 80 sccm to 200 sccm. A thickness of the SiGe epitaxy layer deposited through said first-stage process of manufacturing the selective area SiGe epitaxy is 1/10˜⅝ e.g. 100 Å to 500 Å of the total thickness of the SiGe epitaxy layer deposited through the multi-stage process of manufacturing the selective area SiGe epitaxy.

After the first-stage process of manufacturing the selective area SiGe epitaxy is performed, the second-stage process of manufacturing the selective area SiGe epitaxy is carried out. The second-stage process of manufacturing the selective area SiGe epitaxy is, for example, performed under a pressure ranging from 10 torrs to 50 torrs and a temperature ranging from 550° C. to 750° C. Said second-stage process is, for example, performed at 660° C. in the chemical vapor deposition reaction chamber. The gas source flowed into the reaction chamber includes a combination of SiH₂Cl₂, GeH₄, and HCl. For example, a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm. A thickness of the SiGe epitaxy layer deposited through said second-stage process of manufacturing the selective area SiGe epitaxy is ⅙˜⅝ e.g. 200 Å to 500 Å of the total thickness of the SiGe epitaxy layer deposited through the multi-stage process of manufacturing the selective area SiGe epitaxy.

After the second-stage process of manufacturing the selective area SiGe epitaxy is performed, the third-stage process of manufacturing the selective area SiGe epitaxy is carried out. The third-stage process of manufacturing the selective area SiGe epitaxy is, for example, performed under a pressure ranging from 5 torrs to 50 torrs and a temperature ranging from 550° C. to 750° C. Said third-stage process is, for example, performed at 660° C. in the chemical vapor deposition reaction chamber. The gas source flowed into the reaction chamber includes a combination of SiH₄, GeH₄, and HCl. For example, a flow rate of SiH₄ ranges from 30 sccm to 200 sccm, a flow rate of GeH₄ ranges from 100 sccm to 200 sccm, and a flow rate of HCl ranges from 80 sccm to 200 sccm. A thickness of the SiGe epitaxy layer deposited through said third-stage process of manufacturing the selective area SiGe epitaxy is 1/10˜⅝ e.g. 100 Å to 500 Å of the total thickness of the SiGe epitaxy layer deposited through the multi-stage process of manufacturing the selective area SiGe epitaxy.

In another embodiment, the selective area epitaxy growth process is a multi-stage process of manufacturing the selective area semiconductor compound epitaxy layer, which comprises three stages or more in the process of manufacturing the selective area SiGe epitaxy layer.

In another embodiment, the semiconductor compound epitaxy layer is a SiGe layer, and the selective area epitaxy growth process is a multi-stage process of manufacturing the selective area semiconductor compound epitaxy, which comprises two stages in the process of manufacturing the selective area SiGe epitaxy layer. A first-stage process of manufacturing the selective area SiGe epitaxy layer uses SiH₂Cl₂ as a silicon-containing precursors, while a second-stage process uses SiH₄ as the silicon-containing precursors. The first-stage process of manufacturing the selective area SiGe epitaxy layer is, for example, performed under a pressure ranging from 10 torrs to 50 torrs and a temperature ranging from 550° C. to 750° C. Said first-stage process is, for example, performed at 660° C. in a chemical vapor deposition reaction chamber. The gas source flowed into the reaction chamber includes a combination of SiH₂Cl₂, GeH₄, and HCl. For example, a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm. A thickness of the SiGe epitaxy layer deposited through said first-stage process of manufacturing the selective area SiGe epitaxy layer is ⅙˜⅚ e.g. 200 Å to 500 Å of the total thickness of the SiGe epitaxy layer deposited through the multi-stage process of manufacturing the selective area SiGe epitaxy layer.

After the first-stage process of manufacturing the selective area SiGe epitaxy layer is performed, the second-stage process of manufacturing the selective area SiGe epitaxy layer is carried out. The second-stage process of manufacturing the selective area SiGe epitaxy layer is, for example, performed under a pressure ranging from 5 torrs to 50 torrs and a temperature ranging from 550° C. to 750° C. Said second-stage process is, for example, performed at 660° C. in the chemical vapor deposition reaction chamber. The gas source flowed into the reaction chamber includes a combination of SiH₄, GeH₄, and HCl. For example, a flow rate of SiH₄ ranges from 30 sccm to 200 sccm, a flow rate of GeH₄ ranges from 100 sccm to 200 sccm, and a flow rate of HCl ranges from 80 sccm to 200 sccm. A thickness of the SiGe epitaxy layer layer deposited through said second-stage process of manufacturing the selective area SiGe epitaxy layer ranges from 100 Å to 1000 Å.

In still another embodiment, the semiconductor compound epitaxy layer is a SiGe layer, and the gas source for implementing the selective area epitaxy growth process is a combination of two different silicon-containing precursors. The combination comprises SiH₄ and SiH₂Cl₂. For example, the selective area epitaxy growth process is a single-stage process of manufacturing the selective area SiGe epitaxy layer, and performed under a pressure ranging from 10 torrs to 50 torrs and a temperature ranging from 550° C. to 750° C., for example, 660° C. in a chemical vapor deposition reaction chamber. The gas source flowed into the reaction chamber includes a combination of SiH₄, SiH₂Cl₂, GeH₄, and HCl. For example, a flow rate of SiH₄ ranges from 40 sccm to 200 sccm e.g. 60 sccm, a flow rate of SiH₂Cl₂ ranges from 20 sccm to 40 sccm e.g. 95 sccm, a flow rate of GeH₄ ranges from 200 sccm to 550 sccm e.g. 390 sccm, a flow rate of HCl ranges from 80 sccm to 260 sccm e.g. 160 sccm, and a flow rate of doping gas boron ranges from 100 sccm to 300 sccm e.g. 240 sccm.

In the above embodiment, the source/drain region 216 is formed first, and then the source/drain region extension 218 is formed. However, in practice, the process sequence can be changed according to the need. For example, in another embodiment, the source/drain region extension 218 can be formed after the gate structure 206 is formed and before the spacers 211 is formed.

Two different silicon-containing precursors are used as the gas source in the selective area epitaxy growth process as is provided in the present invention, so as to form the SiGe layer which is the main material of the source/drain region. Using SiH₄ characterized in a better absorption as the silicon-containing precursors can reduce a micro-loading effect. On the other hand, using SiH₂Cl₂ characterized in a better lateral growing capability can cover the top of the isolation structure. With a proper use of said two gases, the micro-loading effect can be reduced from 28% to 14%, and no gap exists between the formed SiGe layer and the isolation structure. In addition, the formed SiGe layer can extend and cover the top corner of the isolation structure. Therefore, ion gain degradation and the large leakage current induced with the use of one silicon-containing precursors through the single-stage process of manufacturing the selective area semiconductor compound epitaxy layer are improved, and the performance of the device is also enhanced.

Although the present invention has been disclosed above by the preferred embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A method of forming a selective area semiconductor compound epitaxy layer, comprising the steps of:
providing a substrate which comprises an exposed monocrystalline silicon region; and
performing a process of manufacturing the selective area semiconductor compound epitaxy layer to form a semiconductor compound epitaxy layer on the exposed monocrystalline silicon region, wherein a gas source for implementing the selective area epitaxy growth process comprises two different silicon-containing precursors.

2. The method of claim 1, wherein the selective area epitaxy growth process is a multi-stage process, and the silicon-containing precursors for implementing the selective area epitaxy growth process are different between adjacent stages.

3. The method of claim 2, wherein the multi-stage process of manufacturing the selective area semiconductor compound epitaxy layer is a multi-stage process of manufacturing a selective area silicon germanium (SiGe) epitaxy layer or of manufacturing a selective area silicon carbide (SiC) epitaxy layer.

4. The method of claim 3, wherein when the multi-stage process of manufacturing the selective area semiconductor compound epitaxy layer is a multi-stage process of manufacturing a selective area silicon germanium epitaxy layer, the multi-stage process of manufacturing a selective area silicon germanium epitaxy layer comprises the following steps:
performing a first stage process of manufacturing the selective area SiGe epitaxy layer with the use of SiH₄ as the silicon-containing precursor; and
performing a second stage process of manufacturing the selective area SiGe epitaxy layer with the use of SiH₂Cl₂ as the silicon-containing precursor.

5. The method of claim 4, wherein the first-stage process of manufacturing the selective area SiGe epitaxy layer is performed before the second-stage process of manufacturing the same.

6. The method of claim 5, wherein:
the first-stage process of manufacturing the selective area SiGe epitaxy layer is performed on the following conditions: a pressure ranging from 5 torrs to 50 torrs; a temperature ranging from 550° C. to 750° C.; the gas source comprising SiH₄, GeH₄, and HCl, wherein a flow rate of SiH₄ ranges from 30 sccm to 200 sccm, a flow rate of GeH₄ ranges from 100 sccm to 200 sccm, and a flow rate of HCl ranges from 80 sccm to 200 sccm; and
the second-stage process of manufacturing the selective area SiGe epitaxy layer is performed on the following conditions: a pressure ranging from 10 torrs to 50 torrs; a temperature ranging from 550° C. to 750° C.; the gas source comprising SiH₂Cl₂, GeH₄, and HCl, wherein a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm.

7. The method of claim 4, wherein a thickness of the semiconductor compound epitaxy layer deposited through the first-stage process of manufacturing the selective area SiGe epitaxy layer is ⅓˜⅚ of a total thickness of the semiconductor compound layer deposited through the multi-stage process of manufacturing the selective area semiconductor compound epitaxy layer.

8. The method of claim 4, wherein the thickness of the semiconductor compound layer deposited through the first-stage process of manufacturing the selective area SiGe epitaxy layer ranges from 500 Å to 1000 Å, and a thickness of the semiconductor compound epitaxy layer deposited through the second-stage process of manufacturing the selective area SiGe epitaxy layer ranges from 100 Å to 500 Å.

9. The method of claim 5, wherein the multi-stage process of manufacturing the selective area SiGe epitaxy layer comprises the following steps:
performing a third-stage process of manufacturing the selective area SiGe epitaxy layer after the second-stage process is carried out, wherein SiH₄ is used as the silicon-containing precursor during the third-stage process.

10. The method of claim 9, wherein:
the first-stage process of manufacturing the selective area SiGe epitaxy layer is performed on the following conditions: a pressure ranging from 5 torrs to 50 torrs; a temperature ranging from 550° C. to 750° C.; the gas source comprising SiH₄, GeH₄, and HCl, wherein a flow rate of SiH₄ ranges from 30 sccm to 200 sccm, a flow rate of GeH₄ ranges from 100 sccm to 200 sccm, and a flow rate of HCl ranges from 80 sccm to 200 sccm;
the second-stage process of manufacturing the selective area SiGe epitaxy layer is performed on the following conditions: a pressure ranging from 10 torrs to 50 torrs; a temperature ranging from 550° C. to 750° C.; the gas source comprising SiH₂Cl₂, GeH₄, and HCl, wherein a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm; and
the third-stage process of manufacturing the selective area SiGe epitaxy layer is performed on the following conditions: a pressure ranging from 5 torrs to 50 torrs; a temperature ranging from 550° C. to 750° C.; the gas source comprising SiH, GeH₄, and HCl, wherein a flow rate of SiH₄ ranges from 30 sccm to 200 sccm, a flow rate of GeH₄ ranges from 100 sccm to 200 sccm, and a flow rate of HCl ranges from 80 sccm to 200 sccm.

11. The method of claim 9, wherein:
a thickness of the SiGe epitaxy layer deposited through the first-stage process of manufacturing the selective area SiGe epitaxy layer is 1/10˜⅝ of a total thickness of the SiGe epitaxy layer deposited through the multi-stage process of manufacturing the selective area semiconductor compound epitaxy layer;
a thickness of the SiGe epitaxy layer deposited through the second-stage process of manufacturing the selective area SiGe epitaxy layer is ⅙˜⅝ of the total thickness of the SiGe epitaxy layer deposited through the multi-stage process of growing the selective area semiconductor compound epitaxy layer; and
a thickness of the SiGe epitaxy layer deposited through the third-stage process of manufacturing the selective area SiGe epitaxy layer is 1/10˜⅝ of the total thickness of the SiGe epitaxy layer deposited through the multi-stage process of manufacturing the selective area semiconductor compound epitaxy layer.

12. The method of claim 9, wherein the thickness of the semiconductor compound epitaxy layer deposited through the first-stage process of manufacturing the selective area SiGe epitaxy layer ranges from 100 Å to 500 Å; the thickness of the semiconductor compound epitaxy layer deposited through the second-stage process of manufacturing the selective area SiGe epitaxy layer ranges from 200 Å to 500 Å; and the thickness of the semiconductor compound epitaxy layer deposited through the third-stage process of manufacturing the selective area SiGe epitaxy layer ranges from 100 Å to 500 Å.

13. The method of claim 4, wherein the first-stage process of manufacturing the selective area SiGe epitaxy layer is performed after the second-stage process of manufacturing the same is carried out.

14. The method of claim 13, wherein:
the first-stage process of manufacturing the selective area SiGe epitaxy layer is performed on the following conditions: a pressure ranging from 5 torrs to 50 torrs; a temperature ranging from 550° C. to 750° C.; the gas source comprising SiH₄, GeH₄, and HCl, wherein a flow rate of SiH₄ ranges from 30 sccm to 200 sccm, a flow rate of GeH₄ ranges from 100 sccm to 200 sccm, and a flow rate of HCl ranges from 80 sccm to 200 sccm; and
the second-stage process of manufacturing the selective area SiGe epitaxy layer is performed on the following conditions: a pressure ranging from 10 torrs to 50 torrs; a temperature ranging from 550° C. to 750° C.; the gas source comprising SiH₂Cl₂, GeH₄, and HCl, wherein a flow rate of SiH₂Cl₂ ranges from 40 sccm to 200 sccm, a flow rate of GeH₄ ranges from 50 sccm to 250 sccm, and a flow rate of HCl ranges from 80 sccm to 260 sccm.

15. The method of claim 13, wherein the thickness of the semiconductor compound epitaxy layer deposited through the second-stage process of manufacturing the selective area SiGe epitaxy layer is ⅙˜⅚ of the total thickness of the semiconductor compound epitaxy layer deposited through the multi-stage process of manufacturing the selective area semiconductor compound epitaxy layer.

16. The method of claim 13, wherein the thickness of the semiconductor compound epitaxy layer deposited through the first-stage process of manufacturing the selective area SiGe epitaxy layer ranges from 200 Å to 500 Å, and the thickness of the semiconductor compound epitaxy layer deposited through the second-stage process of manufacturing the selective area SiGe epitaxy layer ranges from 100 Å to 1000 Å.

17. The method of claim 1, wherein the gas source for implementing the selective area epitaxy growth process is a combination of the two different silicon-containing precursors.

18. The method of claim 17, wherein the combination comprises SiH₄ and SiH₂Cl₂.

19. A semiconductor device, comprising:
a silicon substrate comprising a trench defining an active region, wherein the active region comprises a pair of concaves;
an isolation structure disposed in the trench;
a doped semiconductor compound epitaxy layer disposed in the pair of concaves and extended to cover a top corner of the isolation structure as a source/drain region; and
a gate structure disposed on the active region between the pair of concaves and extended to a portion of the isolation structure.

20. The semiconductor device of claim 19, wherein the doped semiconductor compound comprises a doped SiGe or a doped SiC.

21. The semiconductor device of claim 19, further comprising a source/drain extension region disposed in the substrate between the source/drain region and the gate structure.
